(19) United States
(12) Patent Application Publication
(10) Pub. No.: US 2023/0059822 A1
(43) Pub. Date: Feb. 23, 2023

(54) TRANSISTOR

(71) Applicant: Japan Display Inc., Tokyo (JP)

(72) Inventors: Akihiro HANADA, Tokyo (JP); Hajime WATAKABE, Tokyo (JP)

(73) Assignee: Japan Display Inc., Tokyo (JP)

(21) Appl. No.: 17/889,402

(22) Filed: Aug. 17, 2022

(30) Foreign Application Priority Data
Aug. 20, 2021 (JP) 2021-135021

(51) Int. Cl. H01L 29/786; H01L 27/12; H01L 29/423; H01L 29/66; G02F 1/1368

(52) U.S. Cl. CPC H01L 29/7869; H01L 27/1225; H01L 29/42384; H01L 29/78618; H01L 29/78648; H01L 29/78696; H01L 29/66969; G02F 1/1368

(57) ABSTRACT

According to one embodiment, a transistor includes a first gate electrode, a second gate electrode, an oxide semiconductor layer disposed between the first gate electrode and the second gate electrode, and a source electrode and a drain electrode each connected to the oxide semiconductor layer, wherein the oxide semiconductor layer includes a channel forming region, a source region, and a drain region, a light irradiation region which is made low-resistance by irradiating light thereto is each formed between the channel forming region and the source region and between the channel forming region and the drain region, and the first date electrode and the second gate electrode have different lengths.

### CROSS-REFERENCE TO RELATED APPLICATIONS

This application is based upon and claims the benefit of priority from Japanese Patent Application No. 2021-135021 filed Aug. 20, 2021, the entire contents of which are incorporated herein by reference.

### FIELD

Embodiments described herein relate generally to a transistor.

### BACKGROUND

There is a proposed technique for display devices, in which a transistor with an oxide semiconductor is provided with a pixel circuit of a display area and a transistor with a silicon semiconductor is provided with a drive circuit of a peripheral area.

### BRIEF DESCRIPTION OF THE DRAWINGS

FIG. 1 is a perspective view of an example of the schematic structure of a display device of an embodiment.

FIG. 2A is a cross-sectional view of an example of the schematic structure of a transistor of the embodiment.

FIG. 2B is a plan view of the transistor of FIG. 2A.

FIG. 3A is a cross-sectional view of an example of a manufacturing process of the transistor.

FIG. 3B is a cross-sectional view of an example of the manufacturing process of the transistor.

FIG. 4 is a cross-sectional view of the transistor irradiated by light from an illumination device.

FIG. 5 is a cross-sectional view of a transistor of a comparative example.

FIG. 6 illustrates gate voltage (voltage VG)-drain current (Id) characteristics of the transistor of the comparative example.

FIG. 7 is a cross-sectional view of a transistor to which light is irradiated from a side surface.

FIG. 8 illustrates the gate voltage-drain current characteristics of the transistor of FIG. 7.

FIG. 9A is a cross-sectional view of another example of the structure of the transistor of the embodiment.

FIG. 9B is a plan view of the transistor of FIG. 9A.

FIG. 10A is a cross-sectional view of an example of a manufacturing process of a transistor.

FIG. 10B is a cross-sectional view of an example of the manufacturing process of the transistor.

FIG. 11 is a cross-sectional view of the transistor irradiated by light from an illumination device.

FIG. 12A is a cross-sectional view of another example of the structure of the transistor of the embodiment.

FIG. 12B is a plan view of the transistor of FIG. 12A.

FIG. 13A is a cross-sectional view of an example of a manufacturing process of a transistor.

FIG. 13B is a cross-sectional view of an example of the manufacturing process of the transistor.

FIG. 14 is a cross-sectional view of the transistor irradiated by external light.

FIG. 15A is a cross-sectional view of another example of the structure of the transistor of the embodiment.

FIG. 15B is a plan view of the transistor of FIG. 15A.

FIG. 16A is a cross-sectional view of an example of a manufacturing process of a transistor.

FIG. 16B is a cross-sectional view of an example of the manufacturing process of the transistor.

FIG. 17 is a cross-sectional view of the transistor irradiated by light from an illumination device.

FIG. 18 is a cross-sectional view of another example of the structure of the transistor of the embodiment.

FIG. 19A illustrates gate voltage (voltage VG)-drain current (Id) characteristics of a transistor using a low defect silicon oxide film.

FIG. 19B illustrates gate voltage (voltage VG)-drain current (Id) characteristics of the transistor using the high defect silicon oxide film.

FIG. 20 is a cross-sectional view of another example of the structure of the transistor of the embodiment.

### DETAILED DESCRIPTION

In general, according to one embodiment, a transistor comprises a first gate electrode; a second gate electrode opposed to the first gate electrode; an oxide semiconductor layer disposed between the first gate electrode and the second gate electrode; and a source electrode and a drain electrode each connected to the oxide semiconductor layer, wherein the oxide semiconductor layer includes a channel forming region, a source region, and a drain region, a light irradiation region which is made low-resistance by irradiating light thereto is each formed between the channel forming region and the source region and between the channel forming region and the drain region, and the first date electrode and the second gate electrode have different lengths.

An object of the embodiment is to provide a transistor of which the deterioration of characteristics can be suppressed.

Embodiments will be described hereinafter with reference to the accompanying drawings. The disclosure is merely an example, and proper changes within the spirit of the invention, which are easily conceivable by a skilled person, are included in the scope of the invention as a matter of course. In addition, in some cases, in order to make the description clearer, the widths, thicknesses, shapes, etc., of the respective parts are schematically illustrated in the drawings, compared to the actual modes. However, the schematic illustration is merely an example, and adds no restrictions to the interpretation of the invention. Besides, in the specification and drawings, the same or similar elements as or to those described in connection with preceding drawings or those exhibiting similar functions are denoted by like reference numerals, and a detailed description thereof is omitted unless otherwise necessary.

A transistor according to one embodiment will now be described in detail with reference to accompanying drawings.

In this embodiment, a first direction X, a second direction Y and a third direction Z are orthogonal to each other, but they may intersect at an angle other than 90 degrees. In the following descriptions, a direction forwarding a tip of an arrow indicating the third direction Z is defined as “above” or “upward” and a direction forwarding oppositely from the tip of the arrow is referred to as “below” or “downward”. Note that the first direction X, the second direction Y and the third direction Z may be referred to as an X direction, a Y direction and a Z direction, respectively.

With such expressions “a second member above a first member” and “a second member below a first member”, the second member may be in contact with the first member or may be remote from the first member. In the latter case, a third member may be interposed between the first member and the second member. On the other hand, with such expressions “a second member on a first member” and “a second member on a first member”, the second member is meant to be in contact with the first member.

In addition, it is assumed that there is an observation position to observe the transistor on a tip side of an arrow in the third direction Z, and viewing from this observation position toward the X-Y plane defined by the first direction X and the second direction Y is referred to as a planar view. Viewing a cross section of the semiconductor substrate in an X-Z plane defined by the first direction X and the third direction Z or a Y-Z plane defined by the second direction Y and the third direction Z is referred to as a cross-sectional view.

### EMBODIMENT

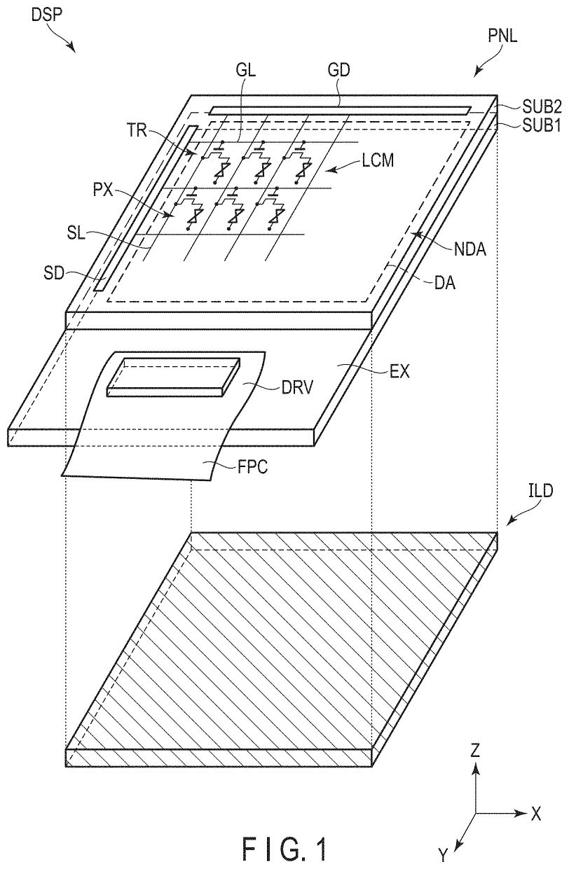

FIG. 1 is a perspective view of an example of the schematic structure of a display device of the present embodiment. The display device DSP includes an illumination device ILD, and a display panel PNL.

The illumination device ILD may include a plurality of light source elements, a light guide plate, or an optical sheet, which are not shown. The illumination device ILD may be a so-called direct-light type or a sidelight type illumination device.

The display panel PNL includes a substrate SUB1, substrate SUB2, and liquid crystal layer (not shown) held between substrates SUB1 and SUB2. An area where the substrates SUB1 and SUB2 overlap has a display area DA and a non-display area NDA. The display area DA includes a plurality of pixels PX, a plurality of signal lines SL (may be referred to as source lines), and a plurality of scan lines GL (may be referred to as gate lines). The non-display area NDA includes a signal line drive circuit SD (may be referred to as source driver) connected to the signal lines SL, and a scan line drive circuit GD (may be referred to as gate driver) connected to the scan line GL.

Each of the plurality of pixels PX includes a transistor TR and a liquid crystal element LCM.

The area of the substrate SUB1 which does not overlap with the substrate SUB2 will be referred to as edge EX. In the edge EX, a flexible printed circuit board FPC and a drive element DRV, which are connected to the signal line SL and the scan line GL, are disposed. The drive element DRV is electrically connected to the signal line SL and the scan line GL via the flexible printed circuit board FPC to input the drive signals to each of the signal line SL and the scan line GL.

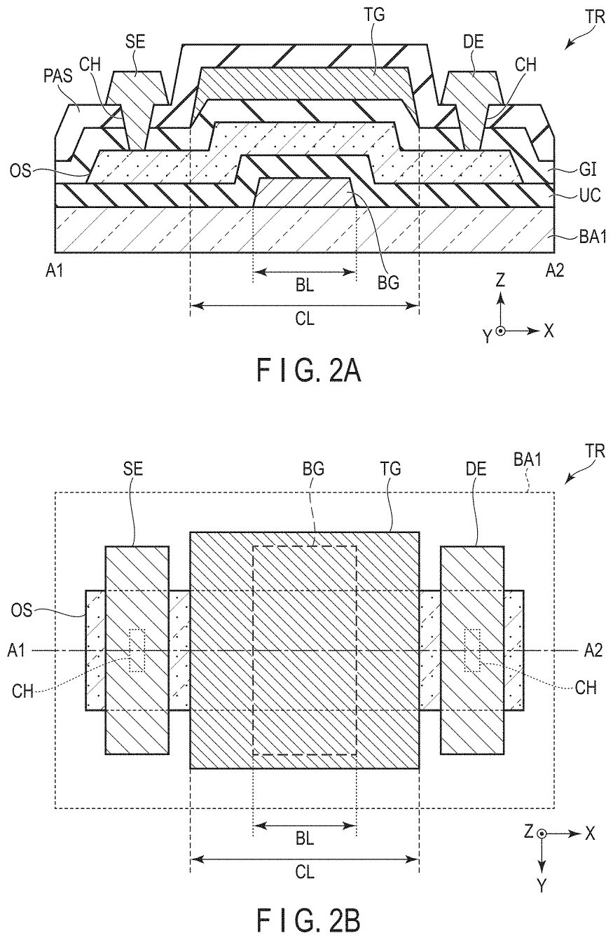

FIG. 2A is a cross-sectional view of an example of the schematic structure of a transistor of the present embodiment. FIG. 2B is a plan view of the transistor of FIG. 2A. The cross-sectional view of the transistor, taken along line A1-A2 of FIG. 2B is illustrated in FIG. 2A.

The transistor TR is disposed on the base material BAl. The transistor TR includes a gate electrode BG, insulating layer UC, oxide semiconductor layer OS, insulating layer GI, gate electrode TG, source electrode SE, and drain electrode DE. The gate electrodes BG and TG may be referred to as bottom gate and top gate, respectively. Alternatively, gate electrodes BG and TG may be referred to as first gate electrode and second gate electrode, respectively.

The material of the substrate BA1 is glass or resin. Such resins include, for example, polyimide resin and acrylic resin.

The gate electrode BG may be formed using, for example, a single-layer metallic film or a laminated film of multiple metallic films. Specific examples include a molybdenum-tungsten alloy (MoW) film or a multilayer film including an aluminum alloy film sandwiched between titanium films.

An insulating layer UC is disposed to cover the gate electrode BG and the substrate BAl. The insulating layer UC blocks impurities from glass and the like and is formed, for example, with a single layer or layers of silicon oxide or silicon nitride. An inorganic material containing oxygen, e.g., silicon oxide, is more suitable as the insulating layer UC.

The oxide semiconductor layer OS is disposed on the gate electrode BG with the insulating layer UC interposed therebetween. The oxide semiconductor layer OS is, for example, formed with indium gallium zinc oxide (IGZO), indium tin zinc oxide (ITZO), zinc oxide nitride (ZnON), and indium gallium Oxide (IGO).

An insulating layer GI is disposed to cover the oxide semiconductor layer OS and the insulating layer UC. The insulating layer GI will be formed using the same material as the insulating layer UC.

The gate electrode TG is disposed on the oxide semiconductor layer OS with the insulating layer GI interposed therebetween. In other words, the oxide semiconductor layer OS is disposed between the opposing gate electrodes BG and TG. A length CL of the gate electrode TG in the first direction X is different from a length BL of the gate electrode BG. Specifically, the length CL is longer than the length BL. That is, the edge of the gate electrode TG does not overlap with the edge of the gate electrode BG in a plan view. If the edge of the gate electrode TG and the edge of the gate electrode BG are coincident, the step difference will become larger, which may cause a decrease in the reliability of the transistor TR. Therefore, it is preferable that the ends do not coincide.

An insulating layer PAS is disposed to cover the gate electrode TG and the insulating layer GI. The insulating layer PAS can be formed using the same material as the insulating layer UC.

The source electrode SE and the drain electrode DE are disposed on the insulating layer PAS. The source electrode SE and drain electrode DE are connected to the oxide semiconductor layer OS through contact holes provided with each of the insulating layers GI and PAS.

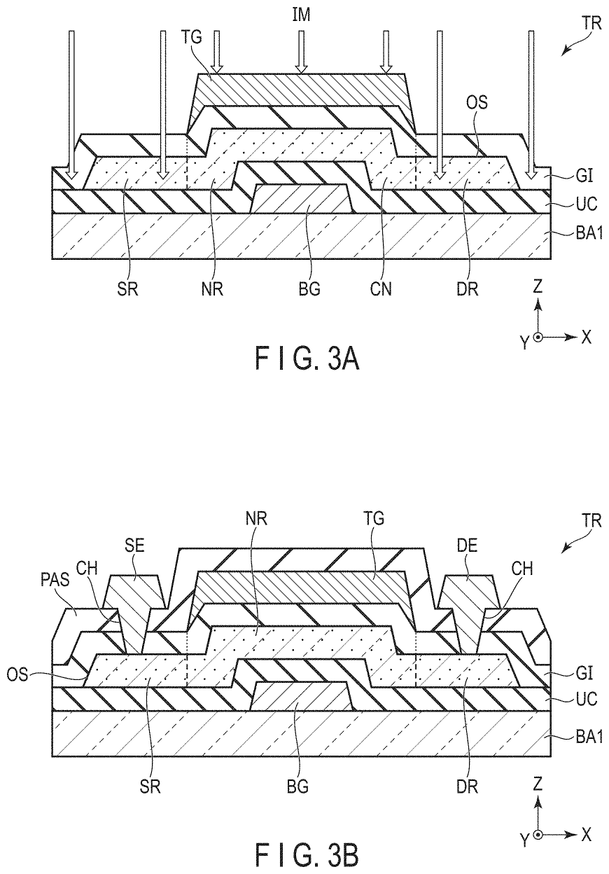

FIGS. 3A and 3B are cross-sectional views illustrating an example of a transistor manufacturing process. FIG. 3A illustrates a process of forming the gate electrode TG on the insulating layer GI, followed by a process of the injection of impurity elements. In the oxide semiconductor layer OS, the region overlapping with the gate electrode TG is the region where the gate electrode TG functions as a mask, and impurity elements IM are not injected. In the oxide semiconductor layer OS, the region not overlapping with the gate electrode TG is the region where the impurity elements IM are injected (cf. FIG. 3A). The region of the oxide semiconductor layer OS where the impurity elements IM are injected corresponds to the source region SR and drain region DR. The region of the oxide semiconductor layer OS where the impurity element IM is not injected is a non-impurity region NR. When the impurity element IM is injected, the oxygen deficiency occurs in the oxide semiconductor layer OS, resulting in low resistance. On the other hand, the non-impurity region NR, where the impurity element IM is not injected, remains high-resistance.

The impurity elements IM include, for example, hydrogen, argon, phosphorus, and boron.

After the impurity element IM is injected, an insulating layer PAS is disposed to cover the insulating layer GI and the gate electrode TG. The insulating layers PAS and GI are partially removed to form contact holes CH. The removed part overlaps with the source region SR and the drain region DR. A metal film is deposited on the insulating layer PAS and selectively removed to form the source electrode SE and the drain electrode DE (cf. FIG. 3B). The source electrode SE and the drain electrode DE are connected to the source region SR and the drain region DR, respectively.

The transistor TR of this example includes an insulating layer PAS between the source electrode SE and the drain electrode DE, and the oxide semiconductor layer OS. A so-called channel etching is not required to form the source electrode SE and the drain electrode DE, and thus, the reliability of the transistor TR can be improved.

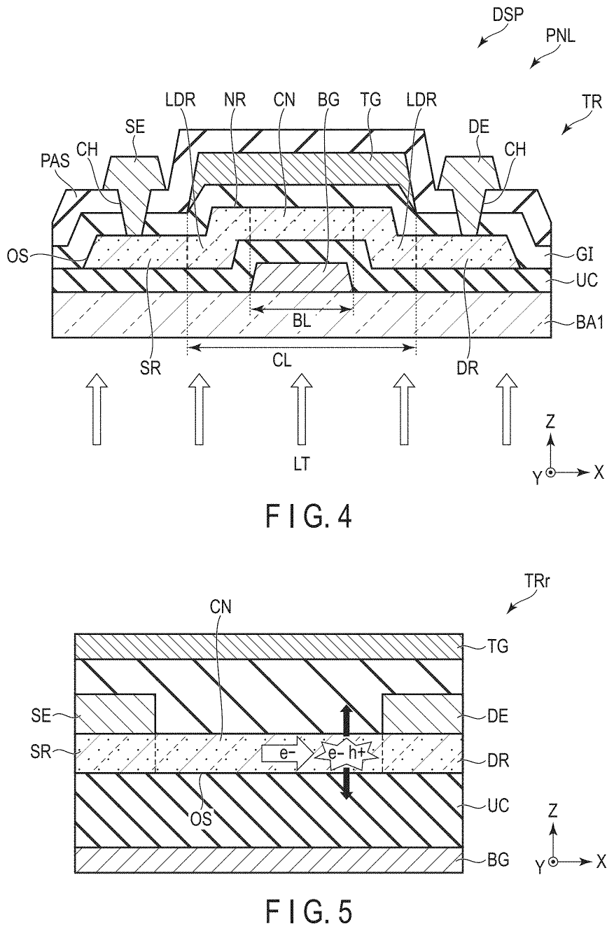

FIG. 4 is a cross-sectional view of a transistor irradiated by light from an illumination device. The transistor TR in the display panel PNL of the display device DSP is irradiated by light LT from the illumination device ILD, which is not shown in the figure, from below during display operation.

The length BL of the gate electrode BG is shorter than the length CL of the gate electrode TG. The light LT is not completely blocked by the gate electrode BG and enters the non-impurity region NR of the oxide semiconductor layer OS.

In the transistor TR shown in FIG. 4, the region of the non-impurity region NR overlapping the gate electrode BG functions as a channel forming region CN. The region of the non-impurity region NR other than the channel forming region CN will be referred to as region LDR. That is, the region LDR is formed between the channel forming region CN and the source region SR, and between the channel forming region CN and the drain region DR.

Here, as a comparative example, a transistor in which a channel forming region and a source region and the channel forming region and a drain region are adjacent to each other will be described. FIG. 5 is a cross-sectional view of a transistor of the comparative example.

The transistor TRr of FIG. 5 includes a gate electrode BG, insulating layer UC, oxide semiconductor layer OS, source electrode SE, drain electrode DE, insulating layer GI, and gate electrode TG. The regions of the oxide semiconductor layer OS overlapping the source electrode SE and the drain electrode DE will be referred to as source region SR and drain region DR, respectively.

In the transistor TRr, the same voltage VG is applied to gate electrodes BG and TG. A voltage VD greater than the voltage VG is applied to the drain electrode DE.

In a case where the voltage VD is high and the voltage VG is low, the electric field concentrates near the drain region DR, and hot carriers (hot electron-hole pairs) may occur. Hot carriers are attracted to the gate electrodes TG and BG and injected into the insulating layer. This is referred to as drain avalanche hot carrier (DAHC) injection.

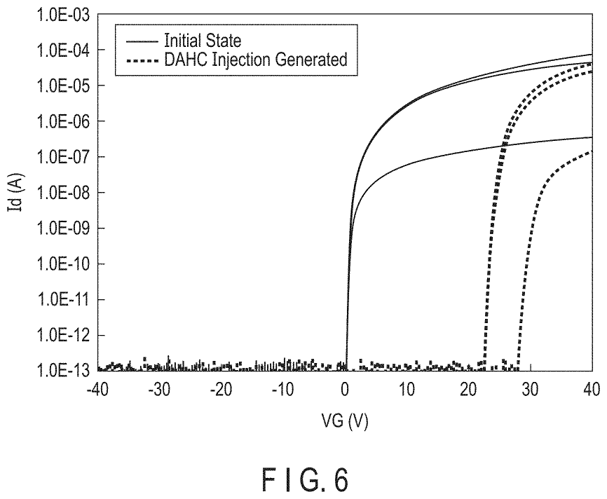

If DAHC injection occurs, a shift in the transistor threshold Vth may occur. FIG. 6 illustrates the gate voltage (voltage VG)-drain current (Id) characteristics of the transistor of the comparative example. The state in which voltages VG and VD are started to be applied will be referred to as initial state. If the application of voltages VG and VD is continued, DAHC injection occurs and the threshold Vth is positively shifted (so called, plus shift). Thus, the transistor TRr may deteriorate in characteristics.

To suppress the deterioration of transistor characteristics, it is suitable to provide a region between the source region and the drain region, and channel forming region to mitigate the electric field concentration. For this purpose, it is preferable that a lightly doped drain (LDD) region is disposed between the source region, drain region, and channel forming region.

FIG. 4 is referred to again here to describe the present embodiment. As described above, the region LDR is disposed between the channel forming region CN and the source region SR, and between the channel forming region CN and the drain region DR.

However, the region LDR is a high-resistance oxide semiconductor layer. In order to use the region LDR as an LDD region, it is necessary to lower the resistance.

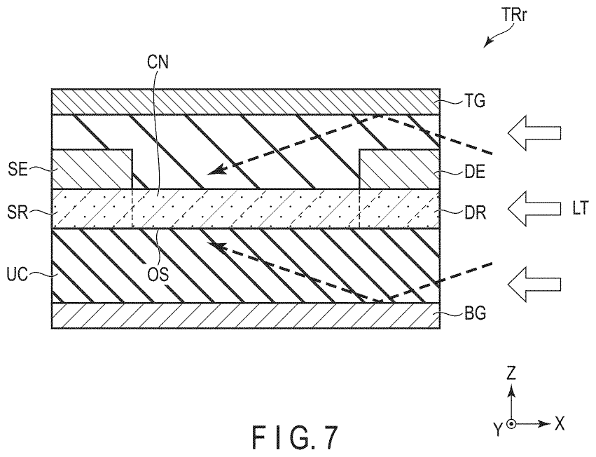

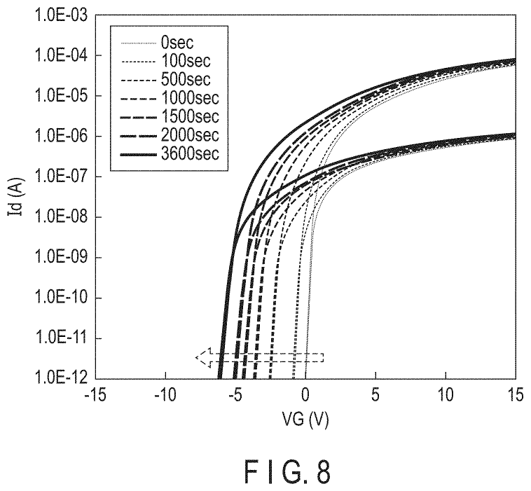

FIG. 7 is a cross-sectional view of a transistor irradiated by light from the side surface. FIG. 8 illustrates the gate voltage-drain current characteristics of the transistor of FIG. 7. Light LT incident from the side surface of the transistor TRr is reflected by gate electrodes TG and BG and propagates in the oxide semiconductor layer OS. In FIG. 8, the gate voltage (voltage VG) and the environmental temperature of the transistor TRr are, respectively, −30V and 60° C. In FIG. 8, the initial state is set to 0 sec (0 second), and characteristics at 100, 500, 1000, 1500, 2000, and 3600 sec are shown.

As in FIG. 8, a threshold Vth of the transistor TRr shifts to minus (so called, minus shift) as the time elapses. That is, the oxide semiconductor layer OS of transistor TRr is becoming lower resistance due to light irradiation.

In the present embodiment, as in FIG. 4, the oxide semiconductor layer OS is made low-resistance by light irradiation to form the LDD region. In the transistor TR, irradiation of light LT from the illumination device ILD causes the region LDR to decrease resistance thereof and to function as an LDD region. The electric field concentration between the channel forming region CN and the drain region DR is mitigated, and the deterioration of characteristics of the transistor TR can be suppressed.

In the present embodiment, the region LDR may be referred to as light irradiation region. The light LT should have a luminous intensity of 100 cd/m² or more. With such luminous intensity, the region LDR can be made sufficiently low-resistance.

The width of the region LDR in the first direction X is, preferably, 1 μm or more. This allows the effect of mitigating the electric field concentration to be sufficient.

In the transistor TR of the present embodiment, the gate electrode TG overlaps with the region LDR functioning as the LDD region. Such a structure will be referred to as gate overlapped LDD (GOLD) structure. In transistors with the GOLD structure, electrons as carriers are stored in the LDD region overlapping the gate electrode, and this allows the resistance of the LDD region to be reduced.

### Configuration Example 1

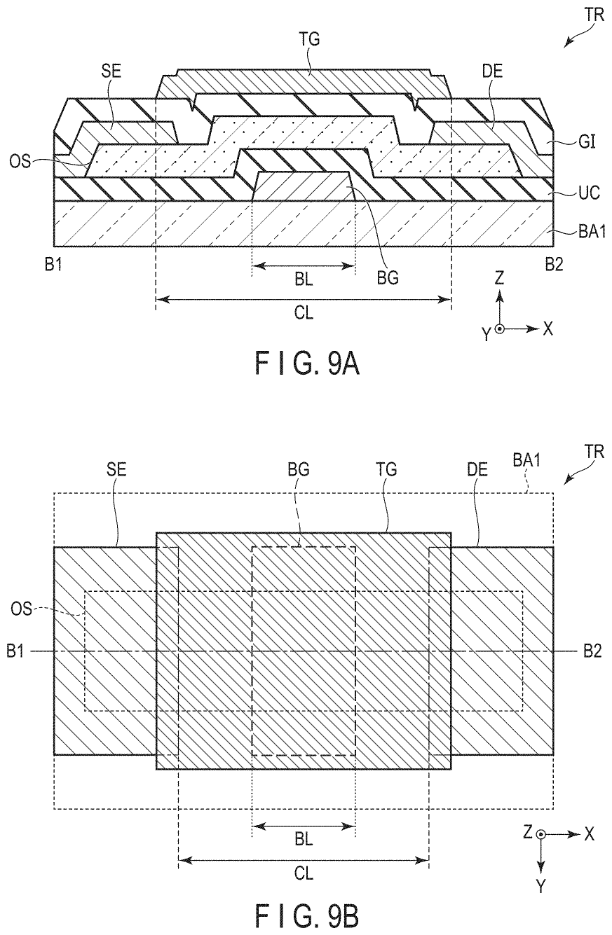

FIG. 9A is a cross-sectional view of another example of the structure of the transistor of the embodiment. The example of FIG. 9A differs from that of FIG. 2A in that the top gate overlaps source and drain electrodes.

FIG. 9B is a plan view of the transistor of FIG. 9A. The cross-sectional view of the transistor, taken along line B1-B2 of FIG. 9B is shown in FIG. 9A.

The transistor TR of FIG. 9A has the same layered structure up to the oxide semiconductor layer OS as the transistor TR of FIG. 2A. The transistor TR of FIG. 9A includes a source electrode SE and a drain electrode DE in direct contact with a portion of the oxide semiconductor layer OS.

An insulating layer GI is disposed to cover the oxide semiconductor layer OS, source electrode SE, and drain electrode DE.

The gate electrode TG is disposed on the oxide semiconductor layer OS with the insulating layer GI interposed therebetween. In other words, the oxide semiconductor layer OS is disposed between the opposing gate electrodes BG and TG. The length CL of the gate electrode TG in the first direction X is longer than the length BL of the gate electrode BG. The edge of the gate electrode TG does not overlap with the edge of the gate electrode BG in a plan view.

The gate electrode TG faces the source electrode SE and the drain electrode, respectively, through the insulating layer GI. Furthermore, the gate electrode TG overlaps with the source electrode SE and the drain electrode DE in a plan view.

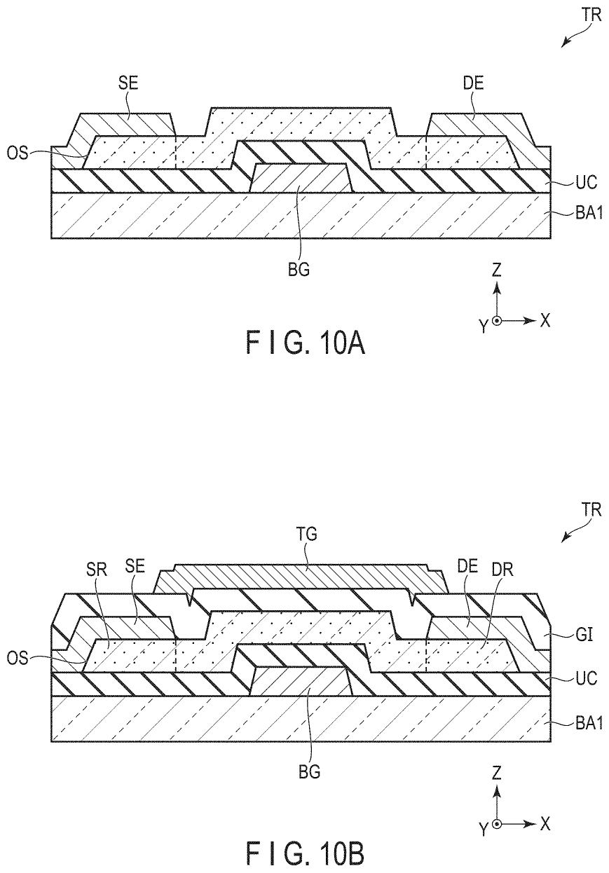

FIGS. 10A and 10B are cross-sectional views illustrating an example of a manufacturing process of the transistor. After forming the oxide semiconductor layer OS, a metal film is deposited and selectively removed to form the source electrode SE and drain electrode DE (cf. FIG. 10A).

By directly contacting the source electrode SE and the drain electrode DE, which are metal films, to the oxide semiconductor layer OS, the contact region is made low-resistance. The low-resistance regions will be referred to as source region SR and drain region DR.

Unlike FIG. 3A, this example does not have the process of injecting impurity elements IM. Thereby, the manufacturing process for the transistor TR can be reduced.

An insulating layer GI is disposed to cover the oxide semiconductor layer OS, source electrode SE, and drain electrode DE.

The gate electrode TG is disposed on the insulating layer GI to be opposed to the gate electrode BG (cf. FIG. 10B). The edge of the gate electrode TG overlaps with the source electrode SE and the drain electrode DE.

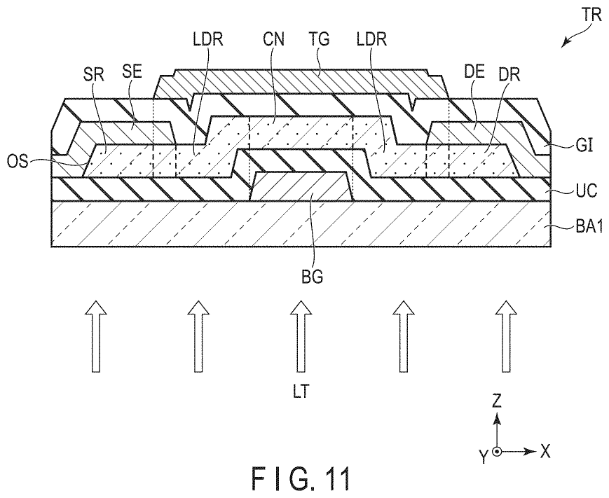

FIG. 11 is a cross-sectional view of a transistor exposed to light from an illumination device. The transistor TR of the display panel PNL of the display device DSP is irradiated by light from the illumination device ILD, which is not shown, from below during display operation. The light LT preferably has a luminous intensity of 100 cd/m² or higher.

As described above, the length CL of gate electrode TG is longer than the length BL of gate electrode BG. The light LT enters the oxide semiconductor layer OS without being completely blocked by the gate electrode TG.

In the transistor TR of FIG. 11, the regions of the oxide semiconductor layer OS overlapping with the gate electrode BG functions as a channel forming region CN.

The channel forming region CN and source region SR, and the region between the channel forming region CN and the drain region DR are, respectively, the region LDR. The region LDR is made low-resistance by irradiation of light LT and functions as the LDD region. The width of the region LDR in the first direction X is, preferably, 1 μm or more. This allows the effect of mitigating the electric field concentration to be sufficient.

In the transistor TR of this example, the gate electrode TG overlaps with the region LDR functioning as the LDD region. That is, as in the embodiment, the transistor TR has a GOLD structure. This allows the resistance of the LDD region to be reduced.

The above example can achieve the same effects of the embodiment.

### Configuration Example 2

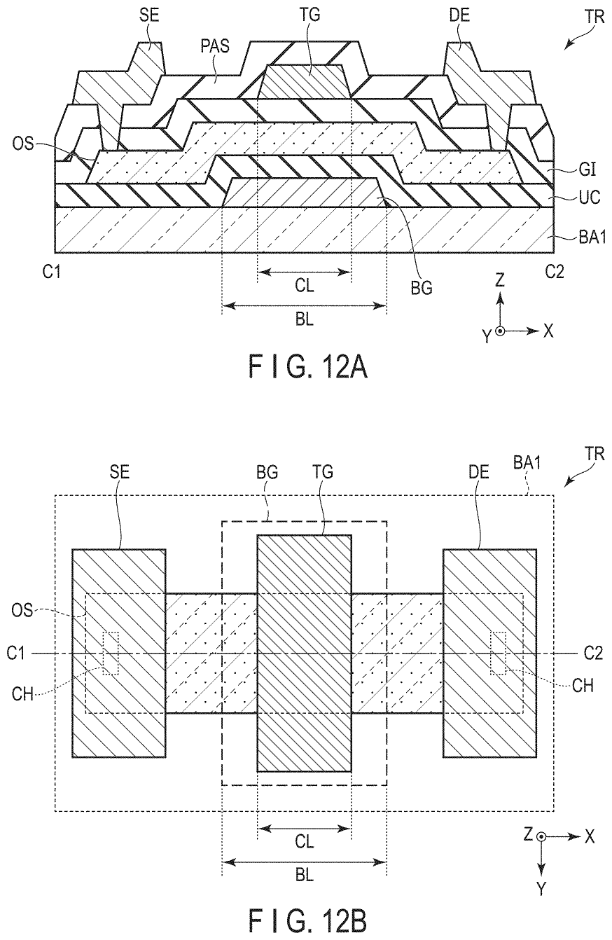

FIG. 12A is a cross-sectional view of another example of the structure of the transistor of the embodiment. The example of FIG. 12A differs from that of FIG. 2A in that the bottom gate is larger than the top gate.

FIG. 12B is a plan view of the transistor of FIG. 12A. The cross-sectional view of the transistor, taken along line C1-C2 of FIG. 12B is shown in FIG. 12A.

The length BL in the first direction X of the gate electrode BG which is a bottom gate is longer than the length CL of gate electrode TG which is a top gate. The edge of the gate electrode TG does not overlap with the edge of the gate electrode BG in a plan view. This is because if the edge of the gate electrode TG and the edge of the gate electrode BG coincide, the step difference will become greater.

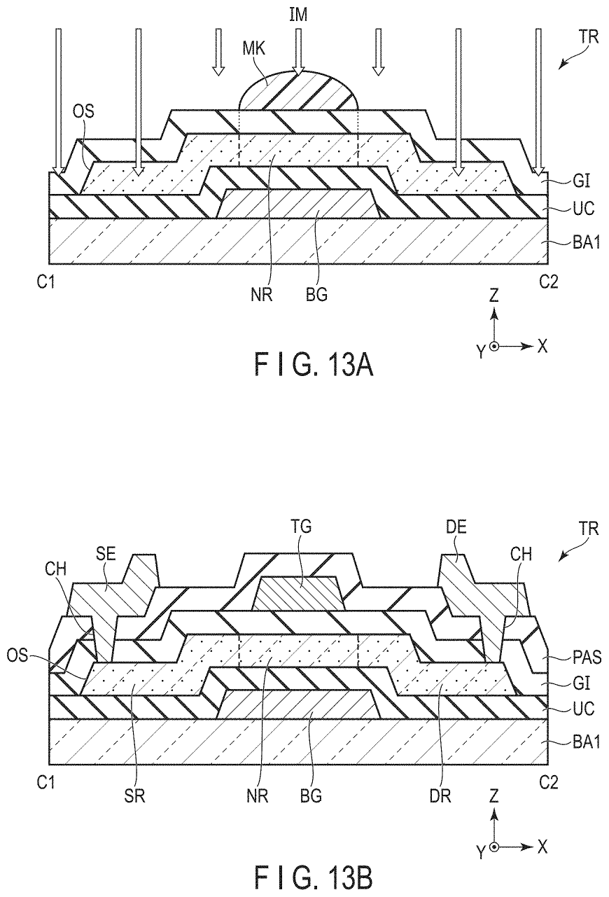

FIGS. 13A and 13B are cross-sectional views illustrating an example of a manufacturing process of the transistor. In FIG. 13A, a mask MK is disposed on the insulating layer GI, and then impurity elements IM are injected. The mask MK may be formed with a resist material. In the region of the oxide semiconductor layer OS overlapping with the mask MK, the impurity element IM is not injected. The impurity element IM is injected into the region of the oxide semiconductor layer OS not overlapping with the mask MK (cf. FIG. 13A).

The region of the oxide semiconductor layer OS where the impurity elements IM are injected corresponds to the source region SR and drain region DR. The region of the oxide semiconductor layer OS where the impurity element IM is not injected is a non-impurity region NR. When the impurity element IM is injected, the oxygen deficiency occurs in the oxide semiconductor layer OS, resulting in low resistance. On the other hand, the non-impurity region NR, where the impurity element IM is not injected, remains high-resistance.

The impurity elements IM include, for example, hydrogen, argon, phosphorus, and boron.

After the impurity element IM is injected, a gate electrode TG is formed on the insulating layer GI. An insulating layer PAS is disposed to cover the insulating layer GI and the gate electrode TG. The insulating layers PAS and GI are partially removed to form contact holes CH. The removed part overlaps with the source region SR and the drain region DR. A metal film is deposited on the insulating layer PAS and selectively removed to form the source electrode SE and the drain electrode DE (cf. FIG. 13B). The source electrode SE and the drain electrode DE are connected to the source region SR and the drain region DR, respectively.

In this example, the mask MK determines the region where the impurity elements IM are injected. Unlike FIG. 3A, the gate electrode TG does not need to be used as a mask. Therefore, the gate electrodes TG and BG, as well as the source electrode SE and drain electrode DE can be separated from each other. Since there is less overlap between the above electrodes, parasitic capacitance can be reduced.

The transistor TR of this example includes an insulating layer PAS between the source electrode SE and the drain electrode DE, and the oxide semiconductor layer OS. A so-called channel etching is not required to form the source electrode SE and the drain electrode DE, and thus, the reliability of the transistor TR can be improved.

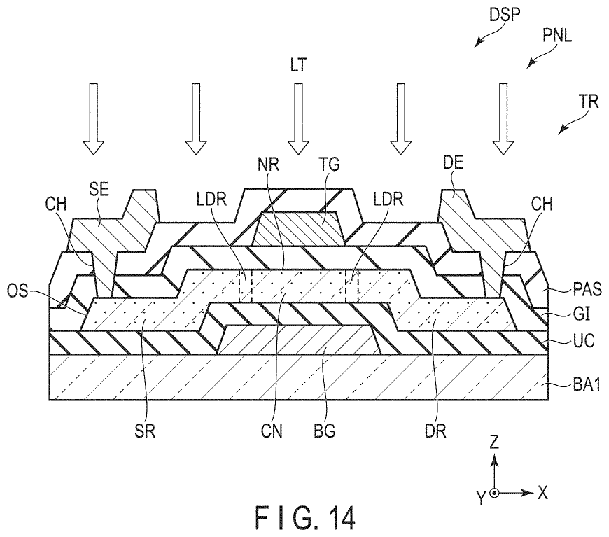

FIG. 14 is a cross-sectional view of a transistor irradiated by light from an illumination device. The transistor TR in the display panel PNL of the display device DSP is irradiated by external light LT. The external light LT is, for example, reflection light which is environment light or light from an illumination device ILD reflected inside the display device DSP. The light LT preferably has a luminous intensity of 100 cd/m² or higher.

The length CL of the gate electrode TG is shorter than the length BL of the gate electrode BG. The light LT is not completely blocked by the gate electrode TG and enters the oxide semiconductor layer OS.

In the transistor TR shown in FIG. 14, the region of the non-impurity region NR overlapping the gate electrode TG functions as a channel forming region CN. The region of the non-impurity region NR other than the channel forming region CN will be referred to as region LDR. That is, the region LDR is formed between the channel forming region CN and the source region SR, and between the channel forming region CN and the drain region DR.

In the transistor TR, the region LDR is made low-resistance by irradiation of external light LT and functions as the LDD region. The electric field concentration between the channel forming region CN and the drain region DR is mitigated, and the deterioration of characteristics of the transistor TR can be suppressed.

The width of the region LDR in the first direction X is, preferably, 1 μm or more. This allows the effect of mitigating the electric field concentration to be sufficient. In the transistor TR of this example, the gate electrode BG overlaps with the region LDR functioning as the LDD region. That is, the transistor TR has a GOLD structure.

The above example can achieve the same effects of the embodiment.

### Configuration Example 3

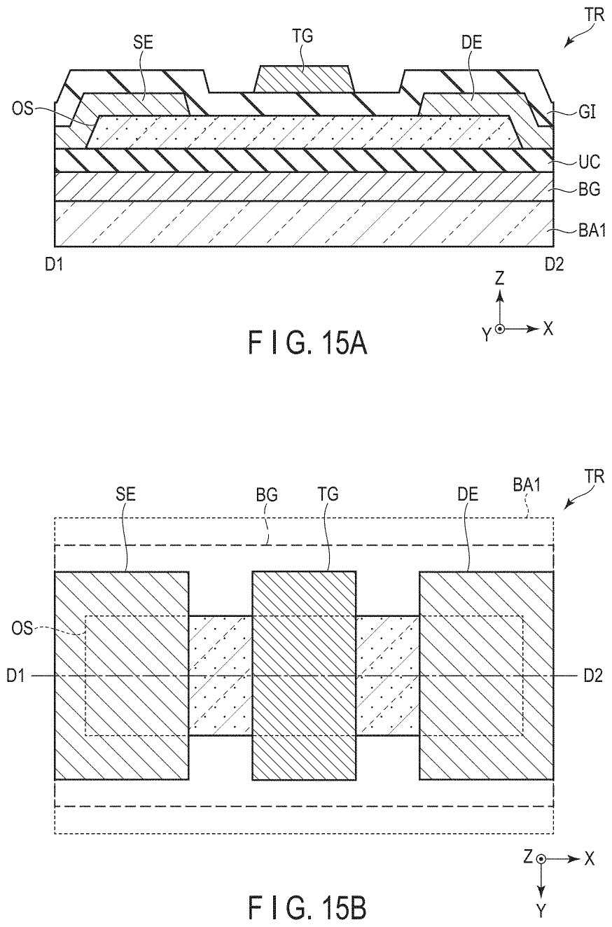

FIG. 15A is a cross-sectional view of another example of the structure of the transistor of the embodiment. The example of FIG. 15A differs from that of FIG. 9A in that the entirety of the oxide semiconductor layer overlaps with the bottom gate.

FIG. 15B is a plan view of the transistor of FIG. 15A. The cross-sectional view of the transistor, taken along line D1-D2 of FIG. 15B is shown in FIG. 15A.

As in FIG. 15B, the gate electrode BG overlaps with the entirety of the oxide semiconductor layer OS, entirety of the gate electrode TG, entirety of the source electrode SE, and entirety of drain electrode DE. The edge of the gate electrode BG does not coincide with any of the edges of the gate electrode TG, source electrode SE, and drain electrode DE.

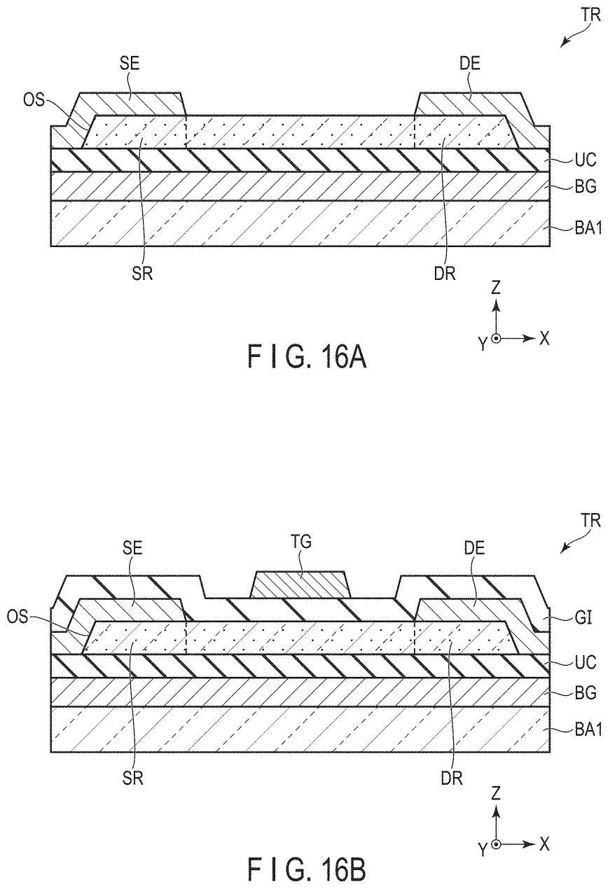

FIGS. 16A and 16B are cross-sectional views illustrating an example of a manufacturing process of the transistor. The gate electrode BG is formed on a base material BAl. The insulating layer UC is formed on the gate electrode BG. The oxide semiconductor layer OS is formed on the insulating layer UC. A metallic film is formed in contact with the oxide semiconductor layer OS and is selectively removed to form the source electrode SE and the drain electrode DE (cf. FIG. 16A).

By directly contacting the source electrode SE and the drain electrode DE, which are metal films, to the oxide semiconductor layer OS, the contact region is made low-resistance. The low-resistance regions will be referred to as source region SR and drain region DR.

The insulating layer GI is disposed to cover the oxide semiconductor layer OS, source electrode SE, and drain electrode DE.

The gate electrode TG is disposed on the insulating layer GI to be opposed to the gate electrode BG (cf. FIG. 16B). The edge of the gate electrode G does not overlap with the source electrode SE or the drain electrode DE.

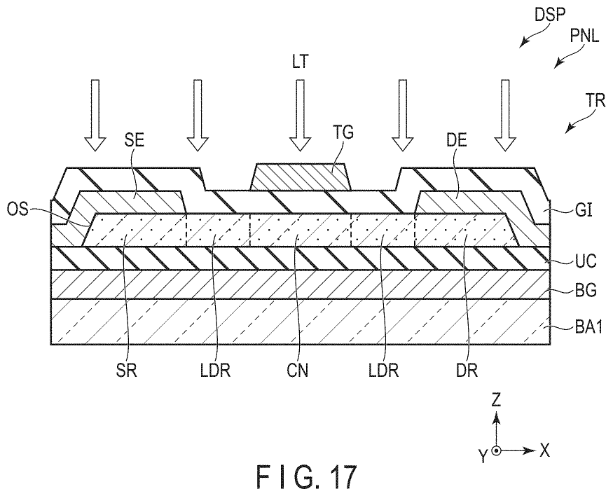

FIG. 17 is a cross-sectional view of a transistor irradiated by light from an illumination device. The transistor TR in the display panel PNL of the display device DSP is irradiated by external light LT. The external light LT is, for example, reflection light which is environment light or light from an illumination device ILD reflected inside the display device DSP. The light LT enters the oxide semiconductor layer OS without being completely blocked by the gate electrode TG. The light LT preferably has a luminous intensity of 100 cd/m² or higher.

In the transistor TR of FIG. 17, the region of the oxide semiconductor layer OS overlapping the gate electrode TG functions as a channel forming region CN.

The channel forming region CN and source region SR, and the region between the channel forming region CN and the drain region DR are, respectively, the region LDR. The region LDR is made low-resistance by irradiation of light LT and functions as the LDD region. The width of the region LDR in the first direction X is, preferably, 1 μm or more. This allows the effect of mitigating the electric field concentration to be sufficient.

In the transistor TR of this example, the gate electrode BG overlaps with the region LDR functioning as the LDD region. That is, the transistor TR has a GOLD structure.

In the transistor TR, the region LDR is made low-resistance by irradiation of external light LT and functions as the LDD region. The electric field concentration between the channel forming region CN and the drain region DR is mitigated, and the deterioration of characteristics of the transistor TR can be suppressed.

The above example can achieve the same effects of the embodiment.

### Configuration Example 4

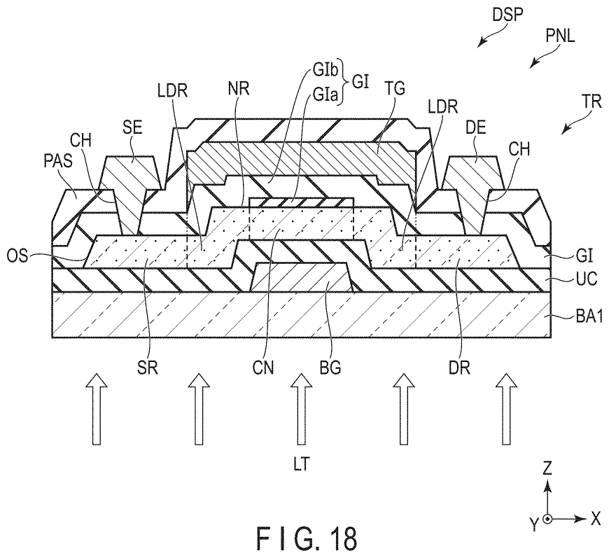

FIG. 18 is a cross-sectional view of another example of the structure of the transistor of the embodiment. The example of FIG. 18 differs from that of FIG. 4 in that the insulating layer GI is double layered.

The transistor TR of FIG. 18 includes, as the insulating layers GI, a lower insulating layer GIa and an upper insulating layer GIb. The insulating layer GIa is in contact with the channel forming region CN of the oxide semiconductor layer OS. The insulating layer GIb covers the oxide semiconductor layer OS and the insulating layer GIa. In particular, the insulating layer GIb is in contact with the region LDR which is the LDD region. The insulating layers GIa and GIb may be referred to as first layer and second layer, respectively. The transistor TR of FIG. 18 is similar to the transistor TR of FIG. 4 other than the insulating layers GIa and GIb.

In this example, silicon oxide films are used as the insulating layers GIa and GIb. Defects in the insulating layer GIa are less than those in the insulating layer GIb. In other words, the insulating layers GIa and GIb are low defect and high defect silicon oxide films, respectively. Alternatively, the defect density of insulating layer GIa is lower than that of the insulating layer GIb. The difference in defect density can be obtained by changing the applied voltage during the formation of the insulating layers GIa and GIb.

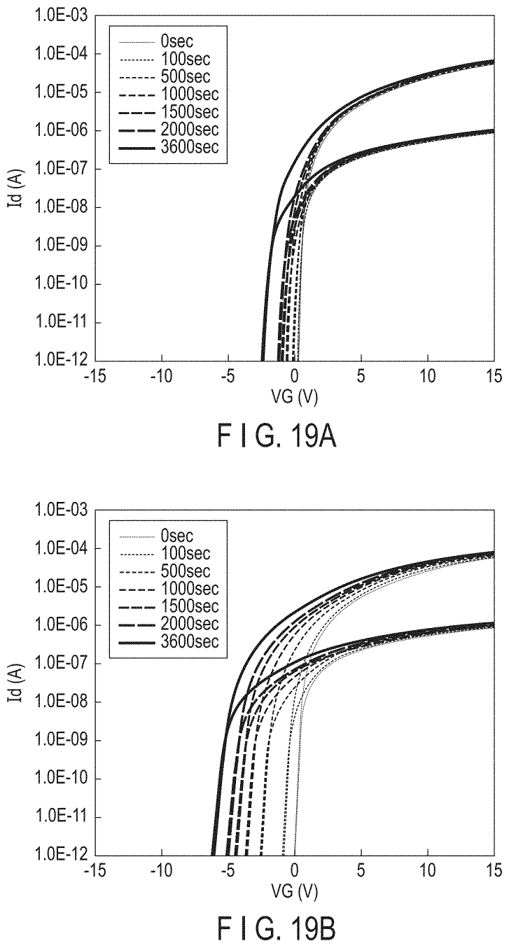

FIGS. 19A and 19B illustrate the gate voltage (voltage VG)-drain current (Id) characteristics of transistors using low defect and high defect silicon oxide films, respectively. FIG. 19A and 19B illustrate the characteristics of the transistor under the same conditions as in FIG. 8, respectively. The threshold Vth of the transistor shifts to minus as the time elapses.

As in FIG. 19A, transistors using a low-defect silicon oxide film as the insulating layer GI have a small shift of threshold Vth. On the other hand, as in FIG. 19B, transistors using a highly defective silicon oxide film as the insulating layer GI has a large shift of threshold Vth.

That is, the oxide semiconductor layer OS of a transistor using a high defect silicon oxide film has a lower resistance than the oxide semiconductor layer OS of a transistor with a low defect silicon oxide film.

If a low defect silicon oxide film is used as the insulating layer GIa, the shift of the threshold Vth of the channel forming region CN in contact with the insulating layer GIa can be suppressed. On the other hand, if a high defect silicon oxide film is used as the insulating layer GIb, the threshold Vth of the region LDR in contact with the insulating layer GIb can be shifted significantly, resulting in lower resistance. In other words, in the transistor TR of FIG. 18, it is possible to lower the resistance of region LDR while keeping the shift of threshold Vth of channel forming region CN low.

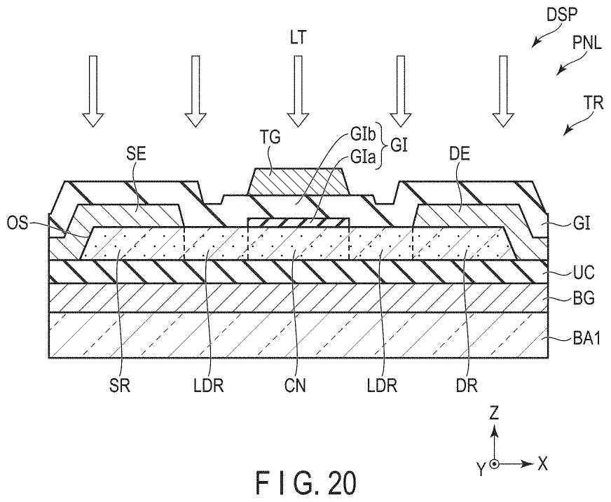

This example can be applied not only to the transistor of FIG. 4, but also to all the transistors mentioned above. FIG. 20 is a cross-sectional view of another example of the structure of the transistor of the embodiment. The transistor TR of FIG. 20 is an application of this example to the structure of FIG. 17.

In the transistor TR of FIG. 20, the insulating layer GIa is in contact with the channel forming region CN, and the insulating layer GIb is in contact with the region LDR. Defects in the insulating layer GIa are fewer than those in the insulating layer GIb.

The above example can achieve the same effects of the embodiment.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A transistor comprising:
a first gate electrode;
a second gate electrode opposed to the first gate electrode;
an oxide semiconductor layer disposed between the first gate electrode and the second gate electrode; and
a source electrode and a drain electrode each connected to the oxide semiconductor layer, wherein the oxide semiconductor layer includes a channel forming region, a source region, and a drain region,
a light irradiation region which is made low-resistance by irradiating light thereto is each formed between the channel forming region and the source region and between the channel forming region and the drain region, and
the first date electrode and the second gate electrode have different lengths.

2. The transistor according to claim 1, wherein
the source region and the drain region each include an impurity element, and
the second gate electrode is longer than the first gate electrode.

3. The transistor according to claim 2, wherein the impurity element is hydrogen, argon, phosphorous, or boron.

4. The transistor according to claim 1, wherein the source electrode and the drain electrode contact the oxide semiconductor layer, and
the second gate electrode is longer than the first gate electrode.

5. The transistor according to claim 1, wherein
the source region and the drain region each include an impurity element, and
the first gate electrode is longer than the second gate electrode.

6. The transistor according to claim 1, wherein
the source electrode and the drain electrode contact the oxide semiconductor layer, and
the first gate electrode is longer than the second gate electrode.

7. The transistor according to claim 1, further comprising an insulating layer between the oxide semiconductor layer and the second gate electrode, wherein
the insulating layer includes a first layer contacting the channel forming region and a second layer contacting the light irradiation region, and
defects included in the first layer are less than defects included in the second layer.

8. The transistor according to claim 1, wherein the light has luminosity of 100 cd/m² or more.
